(19) United States
(12) Patent Application Publication
(10) Pub. No.: US 2025/0255171 A1
(43) Pub. Date: Aug. 7, 2025

(54) LOW BANDGAP DONOR-BASED INDOOR PHOTOVOLTAIC CELL AND ITS DEVICE

(71) Applicant: UNIVERSITY OF SEOUL INDUSTRY COOPERATION FOUNDATION, Seoul (KR)

(72) Inventors: Hyeok KIM, Seoul (KR); Swarup BISWAS, Seoul (KR); Yong Ju LEE, Sacheon-si (KR); Hyo Jeong CHOI, Seoul (KR)

(21) Appl. No.: 19/042,867

(22) Filed: Jan. 31, 2025

(30) Foreign Application Priority Data
Feb. 2, 2024 (KR) 10-2024-0016779

(51) Int. Cl. H10K 85/10; H10K 30/86; H10K 85/20

(52) U.S. Cl. CPC H10K 85/113; H10K 85/111; H10K 85/141; H10K 85/215; H10K 30/86

(57) ABSTRACT

The present invention relates to a low bandgap donor-based indoor photovoltaic cell using PPY:PSS coated with a PTB7-Th:PC₇₀BM layer as a hole transport layer (HTL) and a device using the same. According to the present invention, an indoor OPV with a higher PCE value than the conventional PEDOT:PSS-based OPVs can be manufactured under the same conditions by using PTB7-Th:PC₇₀BM layer-coated PPY:PSS as a hole transport layer (HTL), and the electrode work function can be reduced by depositing a LiF interlayer, thereby performing more effective electron extraction.

### CROSS-REFERENCE TO RELATED APPLICATION

This application claims priority to and the benefit of Korean Patent Application No. 10-2024-0016779, filed on Feb. 2, 2024, the disclosure of which is incorporated herein by reference in its entirety.

### FIELD OF THE INVENTION

The present invention relates to an indoor photovoltaic cell and a device using the same, and more particularly, to an indoor photovoltaic cell using a low bandgap donor as an active material by using PPY:PSS as a hole transport layer (HTL) and a device using the same.

### DISCUSSION OF RELATED ART

Recently, the rapid spread of Internet of Things (IoT) networks has enabled fast and automated technology-based living. In 2025, it is expected that a major part of our daily lives will be mediated through more than 75 billion low-power IoT devices such as sensors, actuators, and healthcare units.

Since most of these IoT devices will be adopted as indoor devices, depending on the application area, the operation of each device should be independent of batteries or grid connections. Therefore, it is essential to develop suitable energy sources that can provide local power to IoT devices. Indoor photovoltaic (IPV) cells are one of the best solutions for powering devices by absorbing indoor light energy.

The radiant intensity of indoor lighting is significantly lower than that of outdoor lighting (e.g., one sun condition) and falls within the visible range (300 to 700 nm). Commercially available inorganic PV cells have been observed to be inefficient as indoor light energy harvesters due to their thick structure and the mismatch between the emission and absorption spectra exhibited in their active layers. Organic photovoltaic (OPV) cells show lower power conversion efficiency (PCE) than inorganic PV cells when operating under 1 sun conditions but exhibit relatively higher performance indoors due to their higher light absorption characteristics within the visible light range. In addition, the OPV cells are lightweight, highly flexible, and ultra-thin, making them suitable as power sources for various small-scale micro-power IoT devices.

Despite these advantages, organic IPV s have not been commercialized yet due to several limitations such as the inability to be universally applied to various indoor light sources, high production costs, short lifetime, and low stability. To overcome these challenges, various strategies are currently being developed, including the development of suitable donor-acceptor materials, optimization of device manufacturing processes and architectures, and the development of various charge transport interlayers (e.g., hole transport layer (HTL) and electron transport layer).

Recently, organic PV cells based on a polymer donor with a lower optical bandgap (˜1.6 eV), namely “poly[4,8-bis(5-(2-ethylhexyl)thiophene-2-yl)benzo[1,2-b;4,5-b′]dithiophene-2,6-diyl-alt-(4-(2-ethylhexyl)-3-fluorothieno[3,4-b]thiophene-)-2-carboxylate-2-6-diyl)] (PTB7-Th)” with a “thieno[3,4-b]thiophene/benzodithiophene backbone,” and “fullerene acceptor ([6,6]-phenyl-C71-butyric acid methyl ester (PC₇₀BM)),” have been reported to demonstrate significantly high PCE under indoor lighting. In this regard, Mori et al. have theoretically calculated that PTB7-Th:PC₇₀BM active layer-based OPVs can exhibit a maximum PCE of 23.1% under a light-emitting diode (LED) lamp. However, experimentally, the maximum PCE of OPVs under an LED lamp was only 11.63%.

In addition, there are various light sources commonly used to illuminate indoor environments, such as LED, fluorescent, halogen, and incandescent lamps, and the emission spectrum of each light source has a different wavelength range. Therefore, the optimal energy bandgap value of the donor material for most efficiently collecting light energy from the light source (according to the Shockley-Queisser limit) is not the same.

For example, high energy bandgap donors (˜2.0 eV) are ideal for light-emitting diodes and fluorescent lamps, while low energy bandgap donors (˜1.0 eV) are ideal for collecting light generated from halogen and incandescent lamps. Consequently, OPVs based on higher energy bandgap donor materials show very low performance under halogen/incandescent lamps, and OPVs based on very low energy bandgap donor materials show very low performance under light-emitting diodes and fluorescent lamps due to large voltage losses.

The material of interest in the present invention is PTB7-Th, which has an optical energy bandgap of ˜1.6 eV, which is neither very high nor very low. Due to its specific optical energy value, PTB7-Th may be a suitable donor for developing OPVs that can operate with reasonable PCE values under all artificial light sources. However, according to previously published reports, there have not been significant efforts to improve the PCE of PTB7-Th:PC₇₀BM active material-based OPVs for operation under indoor lighting conditions.

Thus, the present inventors propose an indoor OPV using PTB7-Th:PC₇₀BM (i.e., low bandgap donor+fullerene acceptor) as an active material through optimal design and careful utilization of a low-cost, easy-to-process, and low-acidity PPY:PSS-based HTL (optimization of processing conditions such as doping concentration and spin coating speed). While devices using a conventional PEDOT:PSS HTL showed a maximum PCE of 14.21% even using an optimized thickness (100 nm) of the active layer (PTB7-Th:PC₇₀BM), the device proposed in the present invention exhibited a maximum PCE of 16.35% under a 1,000 lx LED lamp.

### SUMMARY OF THE INVENTION

### Technical Problem to be Solved

The present invention is directed to providing an indoor photovoltaic cell (OPV) with an improved PCE value compared to the related art.

### Technical Solution

According to an aspect of the present invention, there is provided an indoor photovoltaic cell using PPY:PSS coated with a PTB7-Th:PC₇₀BM layer as a hole transport layer (HTL) and a device using the indoor photovoltaic cell.

The present invention also provides an indoor photovoltaic cell and a device using the indoor photovoltaic cell, wherein the PTB7-Th:PC₇₀BM layer has a PTB7-Th:PC₇₀BM weight ratio of 1.5:1.

The present invention also provides an indoor photovoltaic cell and a device using the indoor photovoltaic cell, wherein a lithium fluoride (LiF) layer is deposited on an upper surface of the PTB7-Th:PC₇₀BM layer.

The present invention also provides an indoor photovoltaic cell and a device using the indoor photovoltaic cell, wherein an Al layer is deposited on an upper surface of the LiF layer.

### Advantageous Effects

According to the present invention, an indoor OPV with a higher PCE value than conventional PEDOT:PSS-based OPVs can be manufactured under the same conditions.

In addition, according to the present invention, by depositing a LiF interlayer, the electrode work function can be reduced, thereby performing more effective electron extraction.

### BRIEF DESCRIPTION OF THE DRAWINGS

FIG. 1 shows the graphs of the FTIR spectrum of a PY 2-based film, the transmittance spectra of various HTL samples in the wavelength range of 370 to 800 nm, the pH values, and the resistivity changes of PPY:PSS according to an increase in PSS concentration.

FIG. 2 shows the atomic force microscopy (AFM) images of various films formed using PY 1, PY 2, PY 3, PY 4, PY 5, and PEDOT:PSS HTL solutions.

FIG. 3 shows a circuit diagram of the OPV device, a graph of changes in simulated JSC, Ideal as the active layer thickness increases, and a graph of the distribution of normalized E² within the OPV device.

FIG. 4 shows the UPS spectra, UV-vis absorption spectra, Tauc plots obtained from the UV-vis absorption spectra of PEDOT:PSS and PY 4, and the energy band diagram of the OPV device.

FIG. 5 shows the graphs of J-V characteristic curves of various OPVs coated with a PY 3 HTL at different spin speeds, J-V characteristic curves of various OPVs, changes in PCE according to the doping concentration of the HTL (PPY:PSS), and the incident photon-to-electron conversion efficiency (IPCE) spectra of OPVs using PY 4 and PEDOT:PSS-based HTLs.

### DETAILED DESCRIPTION OF EXEMPLARY EMBODIMENTS

The purpose and effects of the present invention will become clearer through the following detailed description, but the purpose and effects of the present invention are not limited to what is stated below. Furthermore, in the description of the present invention, when it is determined that a detailed description of known technology related to the present invention may unnecessarily obscure the essence of the present invention, the detailed description thereof will be omitted.

Hereinafter, embodiments of the present invention will be described in detail with reference to the attached drawings so that those skilled in the art can easily implement the present invention. However, the present invention may be implemented in various forms and thus is not limited to the embodiments disclosed below. In addition, in order to clearly disclose the present invention in the drawings, parts not related to the present invention are omitted, and identical or similar symbols in the drawings indicate identical or similar components.

The present invention proposes an indoor organic photovoltaic (OPV) with an improved PCE by using PPY:PSS as a hole transport layer (HTL).

Recently, OPV devices based on poly[4,8-bis(5-(2-ethylhexyl)thiophen-2-yl)benzo[1,2-b: 4,5-b′]dithiophene-2,6-diyl-alt-(4-(2-ethylhexyl)-3-fluorothieno[3,4-b]thiophene-)-2-carboxylate-2-6-diyl)]-(PTB7-Th-) have shown interesting behavior when tested under indoor lighting conditions.

Theoretically, OPVs based on a PTB7-Th:[6,6]-phenyl-C71-butyric acid methyl ester (PC₇₀BM) active layer may exhibit a power conversion efficiency (PCE) of 23% or more under light-emitting diode (LED) illumination. However, the experimentally achieved PCE to date (˜11.63%) is significantly lower than the theoretical PCE. Therefore, the present inventor have designed an indoor OPV with a PTB7-Th:PC₇₀BM active layer and low-acidity, low-cost polypyrrole:polystyrene sulfonate (PPY:PSS) as a hole transport layer (HTL) by optimizing the active layer thickness and processing conditions (spin coating speed and doping concentration) of the HTL through optical simulations and experiments.

Referring to the content to be described below, it can be seen that a device with a 100 nm thick active layer and a PPY:PSS-based HTL (PPY:PSS; PPY:PSS weight ratio of 1:2) coated at 5,000 rpm may exhibit a record high PCE value (16.35%) when operating under a 1,000 lx LED lamp. In contrast, commercial PEDOT:PSS-based OPVs may achieve a maximum PCE of 14.21% under the same conditions. In other words, according to an embodiment of the present invention, an indoor photovoltaic cell with a PCE 2.14% higher than the conventional technology may be manufactured.

Before examining the improved PCE value of an OPV with a PPY:PSS-based HTL according to an embodiment of the present invention with reference to the drawings, a manufacturing method of an OPV according to an embodiment of the present invention will be described in detail.

### Materials for Use

PTB7-Th and PC₇₀BM (>99% purity) were purchased from 1-Material Inc. Anhydrous chlorobenzene (CB) (>99.8% purity) and isopropanol (70% in water) were supplied by Sigma-Aldrich. Pyrrole (PY) (>98% purity, purified twice through vacuum distillation) and PSS (MW 70000) were supplied by Alfa Aesar. Ammonium persulfate (APS) (>98% purity) was supplied by Samchun Chemicals, Clevios AI 4083 PEDOT:PSS (1.3-1.7 wt % in water) was supplied by Heraeus Epurio, and deionized water (18 MΩ) was prepared using a pure reverse osmosis system (RO 15). Additionally, patterned ITO-coated glass was supplied by All for LAB.

### Solution Preparation

A PTB7-Th:PC₇₀BM mixed solution was prepared by mixing PTB7-Th and PC₇₀BM in CB through constant stirring (50° C.) for 12 hours in a glovebox (GB). PTB7-Th and PC₇₀BM have a fixed weight ratio of 1.5:1. The concentration of the solution was set at 20 mg/mL.

### Synthesis of HTL

In the present invention, a PPY:PSS HTL was synthesized through a simple chemical route. First, 100 μL of PY was dissolved in 15 mL of DI water and stirred at 1,000 rpm for 1 hour to prepare 5 batches of PY solution in water. Afterward, fixed PSS concentrations (50, 100, 150, 200, and 250 mg) were mixed into various batches and rapidly stirred at 1,000 rpm for 5 hours.

Meanwhile, 335 mg of APS was mixed in 7.5 mL of DI water and vigorously stirred for 1 hour to prepare 5 APS solutions, which were then stored at 0 to 5° C. for 3 hours.

Afterward, these APS solutions were combined with the 5 prepared PY:PSS solutions and stirred at 1,000 rpm for 12 hours to complete the polymerization and produce a black water-stable polymer.

The final materials were named PY 1, PY 2, PY 3, PY 4, and PY 5, corresponding to PSS concentrations of 50, 100, 150, 200, and 250 mg in PPY:PSS, respectively.

### Device Manufacture

To manufacture the OPV device, the ITO (patterned)-coated glass substrate was first cleaned by ultrasonication in detergent and then rinsed using DI water. Subsequently, the substrate was ultrasonicated in DI water, acetone, and 2-propanol, blown by an N₂ spray gun, and treated with O₂-plasma (15 min). Afterward, an HTL was formed by spin-coating PPY:PSS and PEDOT:PSS (reference) onto the substrate. At this time, to optimize the spin speed, the manufactured OPVs were coated with PPY:PSS at 3,000, 5,000, and 6,000 rpm to form HTLs.

The substrate was then heated at 120° C. for 30 minutes to remove water from the HTL. Afterward, the HTL-coated substrate was transferred to a glovebox (GB) filled with N₂, and the HTL was spin-coated (3,000 rpm for 30 s) with the PTB7-Th:PC₇₀BM solution.

The substrate was heated again in the GB at 130° C. (30 min). Using a shadow mask, an ultra-thin (0.5 nm) lithium fluoride (LiF) layer was deposited onto the PTB7-Th:PC₇₀BM layer in a thermal evaporation system (vacuum) (deposition rate: 0.01 to 0.02 nm/s, pressure: ˜1 μPa). The LiF interlayer was used to reduce the electrode work function for more effective electron extraction. The LiF interlayer also acted as a buffer layer during the deposition of an upper electrode through thermal evaporation to block metal migration into the active layer.

Finally, a 100 nm thick Al layer was deposited on the previously deposited LiF (deposition rate: 0.5 to 0.6 nm/s, pressure ˜1 μPa) to complete the device manufacturing process. The active area of the OPV was 0.0225 cm².

### Characteristic Analysis Method

First, the synthesis of PSS-doped PPY was verified using high-resolution Fourier transform infrared (FT-IR) spectroscopy of PPY:PSS films in the range of 4,000 cm⁻¹ to 400 cm⁻¹. The FTIR spectra were recorded using a PerkinElmer FTIR spectrometer. The transmittance and absorbance spectra (300 to 900 nm) of the samples were recorded using a Shimadzu UV-2401PC UV-vis spectrophotometer. The samples were also analyzed using ultraviolet photoelectron spectroscopy (UPS) with an AXIS Ultra DLD system equipped with an Hel (21.2 eV) source.

Scanning electron microscope (SEM) images of HTLs were recorded by a JEOL JSM 7610F SEM. The surface profiles of various films manufactured using PSS-doped PPY and PEDOT:PSS were analyzed using a PSIA XE-100 atomic force microscope (AFM). Changes in current density (J) with respect to a voltage (V) for the manufactured OPVs were recorded by a Keithley SMU 2401, Cleveland, OH, source meter (programmed).

A solar simulator (McScience) equipped with a 1,000 lx (280 μW/cm) LED lamp (white linear COB LED, McScience) was used as a light source. The active area of the manufactured OPV was estimated using an optical microscope (Olympus). The incident photon to current efficiency (IPCE) values of various OPV devices as a function of wavelength were measured using an ORIEL IQE 200 IPCE measurement equipment.

### Optical Simulation Conditions

The present invention utilized Lumerical finite-difference time-domain (FDTD) solution software to conduct two-dimensional optical simulation-based research on indoor OPV devices. The optical characteristics of each layer were specified by including wavelength-dependent refractive index (n) and extinction coefficient (k) values, and the device length and width were both considered to be 1,000 nm.

The thickness of ITO, HTL, LIF, and Al layers were considered to be 150, 40, 0.5, and 100 nm, respectively. The active layer thickness was varied from 10 to 250 nm at fixed intervals of 5 nm. To minimize the impact on simulation results, the device structure was meshed with the optimal mesh density (mesh accuracy: 3, minimum mesh step: 0.25 nm, dt stability factor: 0.99, override x, y, and z mesh: 0.001). Afterward, two perfectly matched layers (PMLs) were placed to limit the simulation region (below the lower electrode and above the upper electrode) along the solar cell axis.

Optical simulations were used to evaluate how the electric field (photogenerated) is distributed due to photon absorption in the photoactive layer. This was used to calculate the photogenerated ideal short-circuit current density (J_{SC,Ideal}) of the indoor OPV, assuming 100% internal quantum efficiency.

Additionally, the present invention assumed that light passes through the indoor OPV device at an angle of 90° to the surface. The system's impulse response was evaluated using a continuous-wave normalized source (1,000 lx LED lighting), and a user-defined power spectrum was provided by multiplying the impulse response by the corresponding source spectrum throughout the simulation.

Hereinafter, the characteristics of an indoor photovoltaic cell according to an embodiment of the present invention will be described with reference to the drawings.

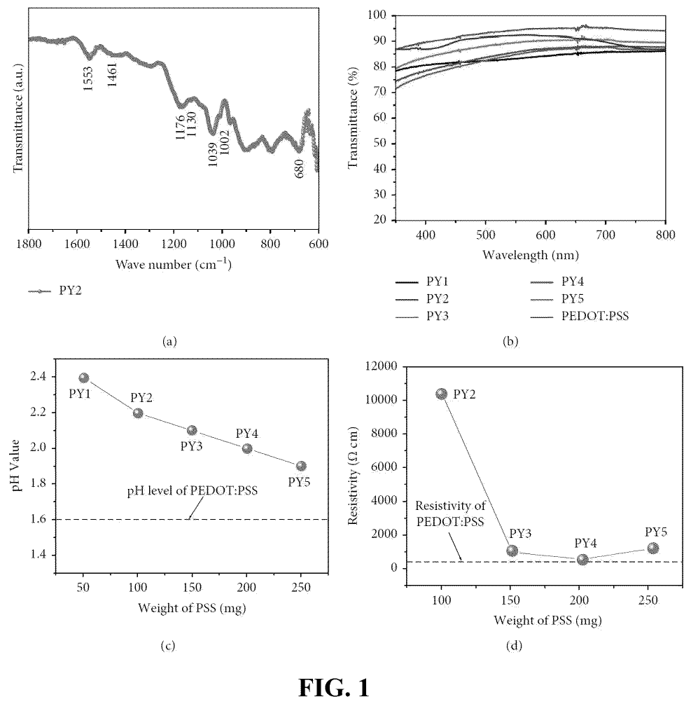

FIG. 1 shows the graphs of the FTIR spectrum of a PY 2-based film, the transmittance spectra of various HTL samples in the wavelength range of 370 to 800 nm, the pH values, and the resistivity changes of PPY:PSS according an increase in PSS concentration.

Specifically, FIG. 1A shows the FTIR spectrum of a PY 2-based film, displaying two sharp dips at ˜1553 and ˜1461 cm⁻¹, which denote the stretching of the PY ring and the stretching of conjugated C—N bonds, respectively. This identified that the synthesized sample was PPY. Furthermore, the presence of PSS within the PPY is confirmed through noticeable dips at ˜1176 ((SO₃H) group stretching), ˜1130 (benzene ring vibration), ˜1039 (sulfur dioxide (SO₂) group stretching), ˜1002 (benzene ring bending vibration), and ˜680 cm⁻¹ (C—S stretching). The dip at 925 cm⁻¹ indicates the doping state of PPY, suggesting that dopant ions are included in the produced polymer.

FIG. 1B shows the transmittance spectra of various HTL samples, namely PY 1, PY 2, PY 3, PY 4, PY 5, and PEDOT:PSS, in the wavelength range of 370 to 800 nm. Clearly, the transmittance values of all samples were 80% or more, and the light transmission performance of PPY:PSS was equivalent to that of commercially available PEDOT:PSS (the average transmittance (AVT) of PY 1-, PY 2-, PY 3-, PY 4-, PY 5-, and PEDOT:PSS-based films are 83.23%, 84.21%, 85.12%, 93.06%, 88.04%, and 90.29%, respectively). Furthermore, PY 4 exhibits higher transmittance than PEDOT:PSS. Therefore, it can be expected that using PY 4 as an HTL allows a large number of photons to be transmitted through the OPV.

It is also noteworthy that the AVT values of PPY:PSS-based films initially increase with the amount of PSS up to a certain point as the PSS concentration increases, and then decrease. The transmittance of films based on this type of material is greatly influenced by two important factors: the film surface morphology and the light absorption (400 to 500 nm) capacity (due to π-π* transitions), which have different effects. Generally, the absorption of PPY:PSS should increase as the doping concentration increases due to the enhancement of π-π* transitions. Consequently, the AVT should decrease with this increase and be at its highest level at the lowest doping concentration. However, at low doping concentrations, the film morphology is very weak, and many pinholes and defects are typically formed due to weak polymer chains.

Additionally, significant photon energy loss may occur due to irregular light scattering. For this reason, PPY:PSS films have lower AVT values at low doping concentrations. In addition to doping, the processability of PPY was improved through PSS. As the amount of PSS increases in PPY:PSS-based films, the quality of the film improves, which is expected to improve the AVT. Therefore, empirically, a PY 4-based HTL shows the highest AVT at the optimal doping level, after which the absorption capacity gradually increases, leading to a decreased AVT as the doping level increases. As the acidity of the HTL may be an important factor affecting the lifetime of OPVs, the acidity of PY 1, PY 2, PY 3, PY 4, PY 5, and PEDO:PSS solutions was measured.

FIG. 1C shows the pH values of various HTL samples, indicating that the pH values of PY 1, PY 2, PY 3, PY 4, PY 5, and PEDO:PSS samples are approximately 2.4, 2.2, 2.1, 2.0, 1.9, and 1.6, respectively. This implies that PEDOT:PSS, due to its high acidity, is not suitable for manufacturing long-lasting OPVs. However, the acidity of PPY:PSS is somewhat lower, making it suitable for use as an HTL in OPVs.

FIG. 1D shows the change in resistivity of PPY:PSS as the PSS concentration increases. Specifically, the resistance of PPY:PSS decreases down to 200 mg (i.e., PY 4) as the PSS doping concentration increases, and then increases. PSS is an insulating organic polymer acid that plays two opposing roles in PPY:PSS. Due to its acidic nature, doping PPY through protonation enhances the conductivity of PPY. In contrast, the insulating behavior may interfere with the charge transport mechanism of PPY:PSS. Therefore, at the optimized PSS concentration, PPY:PSS exhibits the lowest resistivity, and above this PSS concentration, PY:PSS shows higher resistivity values. Notably, the resistivity value of PY 4 is almost identical to that of PEDOT:PSS, making it suitable for application as an HTL.

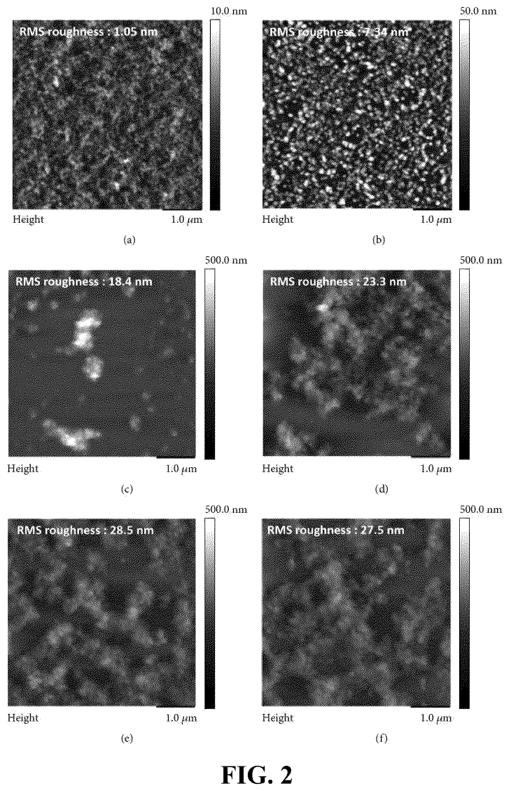

FIG. 2 shows the atomic force microscopy (AFM) images of various films formed using PY 1, PY 2, PY 3, PY 4, PY 5, and PEDOT:PSS HTL solutions.

The root mean square values of the surface roughness of films manufactured using PY 1, PY 2, PY 3, PY 4, and PY 5 HTL samples are approximately 7.34, 18.4, 23.3, 28.5, and 27.5 nm, respectively, which is in stark contrast to the root mean square value of films manufactured using PEDOT:PSS as an HTL (only ˜1.05 nm). The surface roughness of the PPY:PSS-based films is much greater than that of the PEDOT:PSS-based film. This may be related to the development of larger PPY:PSS nanoparticles compared to PEDOT:PSS nanoparticles. This trend corresponds to changes in HTL conductivity and AVT values.

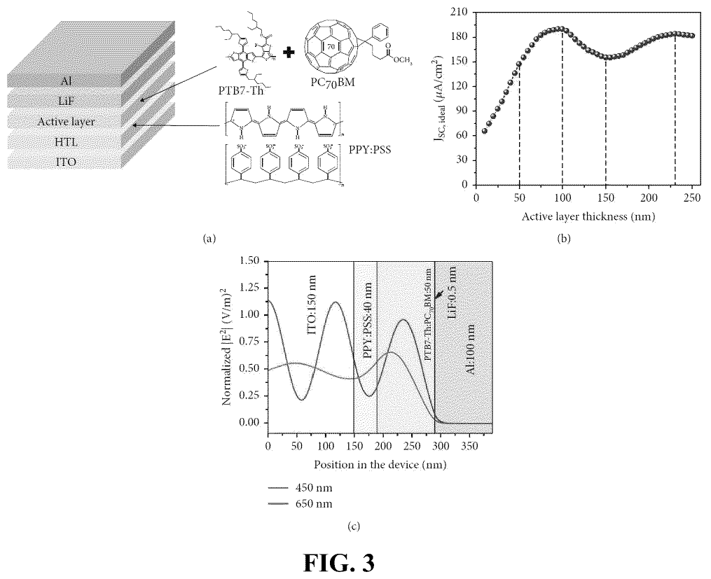

FIG. 3 shows a circuit diagram of the OPV device, a graph of changes in simulated J_{SC,Ideal} as the active layer thickness increases, and a graph of the distribution of normalized E² within the OPV device.

According to reports, the performance of OPV devices is largely dependent on the thickness of the active layer. Therefore, to reduce experimental costs and time before manufacturing actual devices, the thickness of the active layer (see FIG. 3A) was optimized through optical simulations using Lumerical finite-difference time-domain (FDTD) solution.

As described above in detail, the optical characteristics of different layers were defined by incorporating frequency-dependent n and k values into the simulation. FIG. 3B shows the relationship between the estimated J_{SC,Ideal} and the active layer thickness of the OPV device for operation under a 1,000 lx LED lamp. Clearly, the J_{SC,Ideal} value of the OPV exhibits an oscillating behavior depending on changes in the active layer thickness. Initially, the J_{SC,Ideal} value increases as the active layer thickness increases, reaching a maximum value at a 100 nm thickness. Afterward, as the thickness of the active layer increases, the J_{SC,Ideal} value decreases to a certain level and then increases again. The oscillating behavior of J_{SC,Ideal} occurs due to interference between incident and reflected light in the active layer of the device. This result may be used to explain the differences in the distribution of normalized electric field intensity (E²) within devices containing active layers with different thicknesses (see FIG. 3C).

FIG. 3C shows the wavelength-dependent distribution of E² within a device including an active layer with an optimized thickness (100 nm). In the present invention, the E² distribution was evaluated at two different wavelengths, 450 nm and 650 nm, because the active layer exhibits the strongest absorption at these wavelengths. It is noteworthy that in FIG. 3C, the peak value of the E² distribution is at the center of the active layer. However, for active layers with thicknesses of 50 nm and 150 nm, E² (active layer) does not show a similar trend and is much lower than that observed in the 100 nm thick active layer. These results confirm that the optimal thickness of the active layer integrated into the manufactured device was about 100 nm, which was used in subsequent studies. The energy levels of various layers in the OPV are also important factors affecting performance. Consequently, it can be seen that the energy levels of different layers should be well-matched.

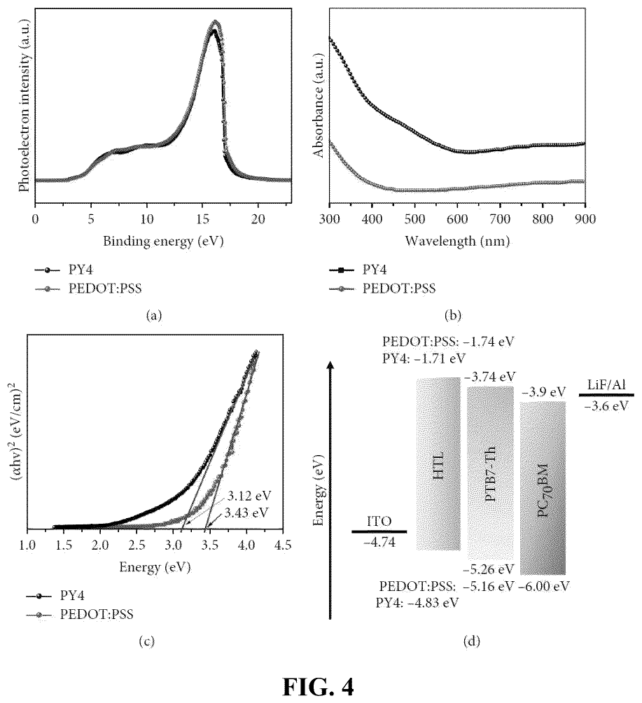

FIG. 4 shows the UPS spectra, UV-vis absorption spectra, Tauc plots obtained from the UV-vis absorption spectra of PEDOT:PSS and PY 4, and the energy band diagram of the OPV device.

To estimate the energy corresponding to the highest occupied molecular orbital (HOMO) and lowest unoccupied molecular orbital (LUMO) of various HTLs, the present invention utilized the UPS (see FIG. 4A) and ultraviolet-visible (UV-vis) absorption spectra (see FIG. 4B) of the respective HTLs. The energy value of the HOMO level (E_{HOMO}) can be calculated through UPS spectrum analysis using the following equation:

$${E}_{HOMO} = hv - W , \qquad ( 1 )$$

where W is the peak width of the UPS spectrum and hv=21:22 eV. Moreover, the energy value of the LUMO level (E_{LUMO}) can be estimated using the following equation:

$${E}_{LUMO} = {E}_{HOMO} - {E}_{g} , \qquad ( 2 )$$

where E_{g} is the energy bandgap. Analysis of the PY 4 and PEDOT:PSS spectra in the UPS analysis revealed that the E_{HOMO} values of PY 4 and PEDOT:PSS were −4.83 and −5.16 eV, respectively. The E_{g} values of these samples were calculated through analysis of UV-vis absorption curves (see FIG. 4C) using the Tauc relationship (Equation 3) as follows:

$$α h v = {A ( h v - {E}_{g} )}^{n} , \qquad ( 3 )$$

where α, v, h, and A denote the absorption coefficient, frequency, Planck's constant, and a constant, respectively. Additionally, due to direct transitions, the n value was considered to be ½. Through this analysis, it was observed that the optical energy bandgaps of PY and PEDOT:PSS are 3.12 eV and 3.42 eV, respectively.

In contrast, the E_{LUMO} of the PY 4 and PEDOT:PSS films are −1.71 eV and −1.74 eV, respectively. Using the HOMO and LUMO energy level values of PY 4 and PEDOT:PSS and extracting the energy values of other layers in the OPV (e.g., ITO, PTB7-Th, PC₇₀BM, LIF, and Al), an energy level diagram of the OPV device is drawn as shown in FIG. 4D.

Notably, the energy value of the HOMO level of the synthesized PPY:PSS is similar to that of the donor's HOMO level. This energy matching may contribute to accelerating the hole movement from the active layer to the positive electrode of the OPV. Moreover, the wide energy bandgap of PPY:PSS (˜3.12 eV) results in a sufficiently low energy (LUMO) level of PPY:PSS (−1.71 eV). The large difference between the LUMO levels of PPY:PSS and the donor PTB7-Th (3.74 eV) is advantageous in blocking the movement of electrons in the opposite direction. Therefore, PPY:PSS is expected to be an effective candidate for use as an HTL in OPVs.

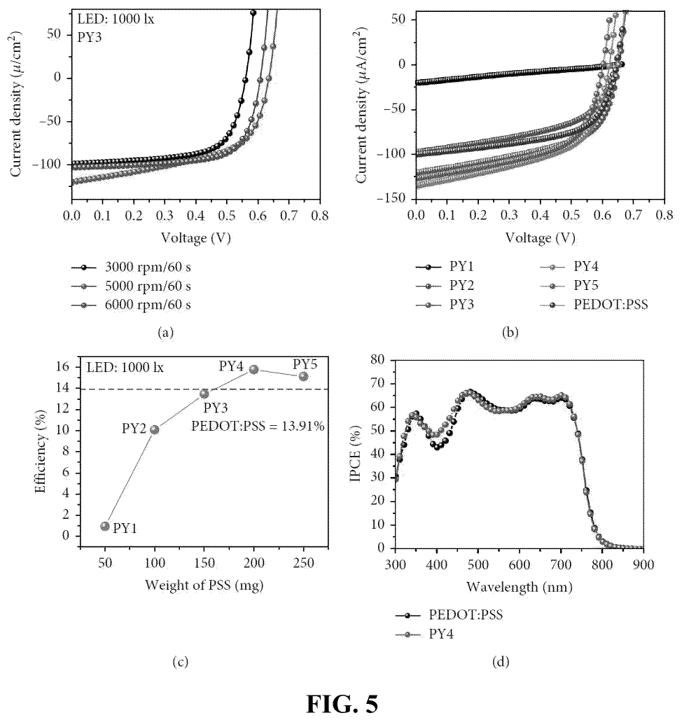

FIG. 5 shows the graphs of J-V characteristic curves of various OPVs coated with a PY 3 HTL at different spin speeds, J-V characteristic curves of various OPVs, changes in PCE according to the doping concentration of the HTL (PPY:PSS), and the incident photon-to-electron conversion efficiency (IPCE) spectra of OPVs using PY 4 and PEDOT:PSS-based HTLs.

Based on the above-described results, OPV devices were manufactured by optimizing the processing conditions (spin coating speed) of PPY:PSS. FIG. 5A shows the J-V characteristic curves of three different OPVs (operating under a 1,000 lx LED lamp) manufactured using a PY 3 (HTL) solution coated at 3,000, 5,000, and 6,000 rpm while keeping the processing conditions of other layers fixed. The device performance parameters estimated from FIG. 5A are summarized in Table 1.

TABLE 1
Summary of device performance parameters (standard deviation
for 8 devices) for PTB7-Th:PC₇₀BM active layer-based OPVs
using a PY 3 HTL deposited at various spin coating speeds

| Spin coating speed (rpm) | V_{OC} (V) | J_{SC} (μA/cm²) | FF (%) | PCEₘₐₓ (PCE_{avg}) (%) |
|---|---|---|---|---|
| 3000 | 0.44 ± 0.01 | 92.3 ± 7.20 | 65.10 ± 1.72 | 11.40 (10.55 ± 0.85) |
| 5000 | 0.65 ± 0.00 | 96.10 ± 4.20 | 55.43 ± 1.00 | 13.45 (13.20 ± 0.25) |
| 6000 | 0.62 ± 0.00 | 97.40 ± 1.83 | 64.07 ± 1.50 | 12.58 (12.03 ± 0.55) |

Clearly, the OPV device with the PY 3 HTL coated at 5,000 rpm shows the highest PCE of 13.45% due to its relatively smooth surface. Next, in the present invention, 6 OPVs were manufactured and tested using HTLs composed of PY 1, PY 2, PY 3, PY 4, PY 5, and PEDOT:PSS under a 1,000 lx LED. FIG. 5B shows the J-V characteristics of these devices under 1,000 lx LED, and Table 2 summarizes the device performance parameters.

TABLE 2
Summary of device performance parameters (standard deviation for 8 devices)
for PTB7-Th:PC₇₀BM active layer-based OPVs using various HTLs

| HTL | V_{OC} (V) | J_{SC} (μA/cm²) | FF (%) | PCEₘₐₓ (PCE_{avg}) (%) | R_{S}(Ω × cm²) | R_{SH} (Ω × cm²) |
|---|---|---|---|---|---|---|
| PY 1 | 0.65 ± 0.03 | 19.6 ± 1.10 | 23.16 ± 3.20 | 1.28 (0.96 ± 0.32) | 27.18 ± 0.51 | 108890 ± 10213 |
| PY 2 | 0.64 ± 0.00 | 97.1 ± 3.90 | 53.27 ± 3.55 | 10.23 (10.08 ± 0.15) | 15.43 ± 0.16 | 146152 ± 14615 |
| PY 3 | 0.65 ± 0.01 | 100.3 ± 5.35 | 56.43 ± 0.94 | 14.09 (13.45 ± 0.64) | 10.20 ± 0.09 | 75223 ± 6411 |
| PY 4 | 0.64 ± 0.00 | 107.1 ± 3.43 | 73.60 ± 0.34 | 16.35 (15.76 ± 0.59) | 8.13 ± 0.21 | 105664 ± 8035 |
| PY 5 | 0.63 ± 0.00 | 105.2 ± 1.70 | 73.3 ± 0.32 | 15.24 (15.11 ± 0.13) | 9.06 ± 0.81 | 95590 ± 8621 |
| PEDOT:PSS | 0.64 ± 0.00 | 100.5 ± 1.85 | 69.76 ± 0.44 | 14.21 (13.98 ± 0.23) | 9.82 ± 1.01 | 66481 ± 5855 |

From Table 2, it can be confirmed that the OPV device performance is highly dependent on the doping concentration of the HTL (i.e., PPY:PSS). Initially, the PCE value (calculated using the relationship PCE=VOC×JSC×FF/Pin, where VOC, JSC, FF, and, Pin denote an open-circuit voltage, a short-circuit current density, a fill factor, and a power intensity of light, respectively) gradually increases as the doping concentration increases, reaching a maximum of 16.35% (a record value for this specific category: low bandgap donor-based OPVs for indoor applications) at a concentration of 200 mg (i.e., PY 4). Thereafter, the PCE value decreases as the doping concentration further increases (see FIG. 5C).

Furthermore, the OPV device using optimally doped PPY:PSS (PY 4) as an HTL shows a higher PCE than the device using commercially available PEDOT:PSS (14.21%) as an HTL. This may be attributed to PY4's lowest resistance, which results in the device's highest J_{SC}, shunt resistance (R_{SH}), lowest series resistance (R_{S}) (R_{SH} and R_{S} values are estimated by Equation 4), and highest ATV value.

$$I = {I}_{L} - {I}_{S} \{ exp ( \frac{( q V + {IR}_{S} )}{n {k}_{B} T} ) - 1 \} - \frac{( V + {IR}_{s} )}{{R}_{SH}} \qquad [ Equation 4 ]$$

where I_{L} is the photogenerated current, I_{S} is the saturation value of the current, R_{S} is the series resistance, V is the voltage, k_{B} is the Boltzmann constant, n is the diode ideality factor, and T is the absolute temperature of the PV cell.

FIG. 5D shows the wavelength-dependent IPCE of OPVs with PY 4 and PEDOT:PSS as HTLs. Notably, both devices exhibit nearly identical IPCE values within the wavelength range of 300 to 900 nm, except for 400 to 500 nm. In the 400 to 500 nm range, the PY 4 HTL-based OPV shows higher IPCE values than the PEDOT:PSS HTL-based OPV. This may be due to the higher transparency of the PY 4 film compared to the PEDOT:PSS film within this wavelength range (see FIG. 1B). Although both exhibit similar resistance values, this could be another reason for the superior performance of PY 4 HTL-based OPVs compared to PEDOT:PSS HTL-based OPVs.

### CONCLUSION

In the prevent invention, an indoor OPV based on PTB7-Th:PC₇₀BM (low bandgap donor) active material was developed through optimization of the active layer thickness and careful utilization of a low-cost, easy-to-process, and low-acidity PPY:PSS-based HTL (optimization of processing conditions such as doping concentration and spin coating speed). The OPV manufactured in this way was able to achieve a record-high (based on PTB7-Th) PCE value of 16.35% under an LED lamp (1,000 lx).

First, the active layer thickness was optimized through optical simulation, which indicated that a 100 nm thick PTB7-Th:PC₇₀BM layer would exhibit maximum absorption of incident photon energy. Next, to develop a high-efficiency indoor OPV with PTB7-Th:PC₇₀BM as an active layer, optimal processing conditions, such as spin coating speed (5,000 rpm) and doping concentration (200 mg; PPY:PSS=1:2), for the newly synthesized low-cost and low-acidity (pH=1.9) PPY:PSS HTL were extracted.

The exemplary embodiments of the present invention described above are disclosed for illustrative purposes, and those skilled in the art will understand that various modifications, alterations, and additions are possible within the spirit and scope of the present invention. Such modifications, alterations, and additions should be considered as falling within the scope of the claims below. Furthermore, those skilled in the art to which the present invention pertains will recognize that various substitutions, modifications, and changes are possible without departing from the technical spirit of the present invention. Accordingly, the present invention is not limited to the embodiments described above and the attached drawings.

In the exemplary systems described above, while the methods are explained based on flowcharts as a series of steps or blocks, the present invention is not limited to the order of steps. Some steps may occur in a different order from or simultaneously with other steps described above. Additionally, those skilled in the art will understand that the steps shown in the flowcharts are not exclusive, and other steps may be included or one or more steps in the flowchart may be omitted without affecting the scope of the present invention.

What is claimed is:

1. An indoor photovoltaic cell using PPY:PSS coated with a PTB7-Th:PC₇₀BM layer as a hole transport layer (HTL) and a device using the indoor photovoltaic cell.

2. The indoor photovoltaic cell and the device using the indoor photovoltaic cell of claim 1, wherein the PTB7-Th:PC₇₀BM layer has a PTB7-Th:PC₇₀BM weight ratio of 1.5:1.

3. The indoor photovoltaic cell and the device using the indoor photovoltaic cell of claim 1, wherein the PPY:PSS has a PPY:PSS doping concentration ratio of 1:2.

4. The indoor photovoltaic cell and the device using the indoor photovoltaic cell of claim 1, wherein a lithium fluoride (LiF) layer is deposited on an upper surface of the PTB7-Th:PC₇₀BM layer.

5. The indoor photovoltaic cell and the device using the indoor photovoltaic cell of claim 4, wherein an Al layer is deposited on an upper surface of the LiF layer.
